(19) United States
(12) Patent Application Publication
(10) Pub. No.: US 2014/0295672 A1
(43) Pub. Date: Oct. 2, 2014

(54) VACUUM PROCESSING APPARATUS AND OPERATING METHOD OF THE SAME

(71) Applicant: Hitachi High-Technologies Corporation, Tokyo (JP)

(72) Inventor: Susumu Tauchi, Tokyo (JP)

(73) Assignee: HITACHI HIGH-TECHNOLOGIES CORPORATION

(21) Appl. No.: 14/182,253

(22) Filed: Feb. 17, 2014

(30) Foreign Application Priority Data
Mar. 29, 2013 (JP) 2013-070951

(51) Int. Cl. H01L 21/677

(52) U.S. Cl. CPC H01L 21/67745
USPC 438/716; 156/345.31

(57) ABSTRACT

A vacuum processing apparatus including an atmospheric transfer chamber including on a front side a plurality of cassette stages on which cassettes having stored samples as processing objects are to be mounted, a first transfer chamber which is disposed via a lock chamber on a back side of the atmospheric transfer chamber and to which a sample decompressed to first pressure is transferred, a second transfer chamber which is disposed on a back side of the first transfer chamber and to which the sample is transferred via a relay chamber from the first transfer chamber, a first processing vessel which is coupled to the first transfer chamber and in which the sample is transferred under the first pressure, and a second processing vessel which is coupled to the second transfer chamber and in which the sample is transferred under the second pressure.

### BACKGROUND OF THE INVENTION

The present invention relates to a vacuum processing apparatus, comprising a plurality of vacuum processing vessels, to process a substrate-shaped sample such as a semiconductor wafer in each of processing chambers disposed in the respective vacuum processing vessels, and in particular, to a vacuum processing apparatus and an operating method of the same in which a plurality of vacuum transfer vessels are coupled to each other, each of the vacuum transfer vessels being coupled to at least one vacuum processing vessel and comprising a transfer chamber in which a sample is transferred through a decompressed space in the transfer chamber, wherein samples are transferred via the transfer chambers between the processing chambers.

In such vacuum processing apparatus, particularly, in a vacuum processing apparatus in which a substrate-shaped sample (to be referred to as a sample or a wafer hereinbelow) such as a semiconductor wafer as an object to be processed is placed in a processing chamber in a decompressed vacuum processing vessel, to conduct etching, by use of plasma produced in the processing chamber, on a film structure including a plurality of films beforehand formed or disposed in layered structure onto each other on an upper surface of a wafer; finer and more precise processing and improvement of wafer processing efficiency have been required. To cope with this problem, there has been developed a vacuum processing apparatus of multi-chamber type including a plurality of vacuum processing vessels to concurrently or sequentially process wafers in the vacuum processing vessels.

It is known that use of such vacuum processing apparatus leads to improvement of productivity per unitary area of the building of the user such as a clean room in which the vacuum processing apparatus is installed. Recently, it has been desired to produce various semiconductor devices by use of one vacuum processing apparatus. To meet a need to conduct processings under different conditions in a plurality of vacuum processing vessels, it is increasingly needed that vacuum processing vessels including containers and processing chambers of various types of configurations and structure are connected to one vacuum processing apparatus.

In the vacuum processing apparatus including a plurality of vacuum processing vessels and a plurality of processing chambers or chambers, gas is supplied and pressure is adjusted according to a condition of each processing independently in the inside of each processing chamber. The processing chambers are ordinarily coupled to a vacuum transfer vessel or a transfer chamber as an internal space thereof in which a robot arm is arranged. The robot arm includes an arm, which holds a wafer on its hand at a tip end thereof to conduct rotation and extension or contraction, and transfers the wafer by using the arm.

The technique described in JP-A-2011-124564 is known as an example of the technique described above. In the vacuum processing apparatus of the prior art, to suppress an event in which the transfer of a wafer affects processing in the processing chamber, the transfer of a wafer is conducted in a vacuum transfer chamber which is decompressed to a level similar to that of the processing chamber and which is filled with gas, for example, inert gas having relatively low reactivity. According to the prior art, the vacuum transfer vessel is coupled with a lock chamber capable of adjusting its internal pressure by increasing or decreasing the pressure between an atmospheric pressure and a predetermined low pressure of vacuum. During the operation of the vacuum processing apparatus, the vacuum transfer vessel and the vacuum processing vessel coupled thereto are kept in a state air-tightly separated from the atmosphere of the external atmospheric pressure. In a decompressed internal space configured by the vacuum transfer vessel and the processing vacuum vessel, a plurality of wafers are transferred from the outside such that each of the wafers is sequentially processed in the space.

### SUMMARY OF THE INVENTION

However, in the prior art, since the following points have not been taken into consideration, problems arise as follows.

That is, consideration has been given only to an arrangement of a vacuum processing vessel in which processing is conducted under a decompressed and predetermined pressure of vacuum, a vacuum transfer vessel, and a transfer intermediate vessel to couple the vessels to each other. That is, consideration has not been given to the following requirement. In a vacuum processing apparatus wherein a first processing chamber in which processing is conducted under a pressure of 100 Pa or less is coupled to a second processing chamber in which processing is conducted under the atmospheric pressure or under a pressure more than the pressure of the first processing chamber and less than the atmospheric pressure, wafers are efficiently transferred to increase processing efficiency of the entire vacuum processing apparatus, for example, to increase the so-called throughput, i.e., the number of wafers processed per unitary time by one vacuum processing apparatus.

According to the prior technique, in an operation of the vacuum processing apparatus wherein a plurality of processing chambers to be used under mutually different conditions of pressure are coupled to a transfer chamber or a vacuum transfer chamber in one vacuum transfer vessel to sequentially and continuously process wafers in the processing chambers, in order to prevent adverse influences including a positional shift of wafers and diffusion and adhesion of contaminating materials and particles due to movement of gas taking place immediately after gate valves to open or close entrances of gates as paths to communicatively connect the chambers to each other are opened, it is required to conduct, before and after the processing, pressure adjustment between the pressure in the vacuum transfer chamber and the pressure suitable for the processing in each processing chamber. In the prior art, consideration has not been given to the problem in which wafer processing efficiency of the entire vacuum processing apparatus is deteriorated as above.

It is therefore an object of the present invention to provide a vacuum processing apparatus having high productivity and an operating method of the same including a plurality of processing chambers to conduct processings for samples under conditions of mutually different processing pressures.

To achieve the object, there is provided a vacuum processing apparatus, comprising:
an atmospheric transfer chamber including on a front side thereof a plurality of cassette stages on which cassettes having stored therein samples as processing objects are to be mounted;
a first transfer chamber disposed on a back side of the atmospheric transfer chamber, the first transfer chamber comprising an inside, any one of the samples transferred through a lock chamber being transferred through the inside decompressed to first pressure;
a second transfer chamber disposed on a back side of the first transfer chamber and coupled to the first transfer chamber via a relay chamber capable of adjusting pressure thereof, the second transfer chamber comprising an inside, the sample transferred from the first transfer chamber being transferred through the inside decompressed to second pressure;
a first processing vessel coupled to the first transfer chamber, the first processing vessel comprising an inside and a processing chamber therein, the sample being transferred to the processing chamber in the inside set to the first pressure and being processed therein; and
a second processing vessel coupled to the second transfer chamber, the second processing vessel comprising an inside and a processing chamber therein, the sample being transferred to the processing chamber in the inside set to the second pressure and being processed therein.

Further, to achieve the object, there is provided an operation method of a vacuum processing apparatus, the apparatus comprising:
an atmospheric transfer chamber including on a front side thereof a plurality of cassette stages on which cassettes having stored therein samples as processing objects are to be mounted;
a first transfer chamber disposed on a back side of the atmospheric transfer chamber, the first transfer chamber comprising an inside, any one of the samples transferred through a lock chamber being transferred through the inside decompressed to first pressure;
a second transfer chamber disposed on a back side of the first transfer chamber and coupled to the first transfer chamber via a relay chamber capable of adjusting pressure thereof, the second transfer chamber comprising an inside, the sample transferred from the first transfer chamber being transferred through the inside decompressed to second pressure;
a first processing vessel coupled to the first transfer chamber, the first processing vessel comprising an inside and a processing chamber therein, the sample being transferred to the processing chamber in the inside set to the first pressure and being processed therein; and
a second processing vessel coupled to the second transfer chamber, the second processing vessel comprising an inside and a processing chamber therein, the sample being transferred to the processing chamber in the inside set to the second pressure and being processed therein, wherein
the relay chamber in which the sample is stored and which is sealed adjusts inner pressure thereof to the first or second pressure of the first or second transfer chamber to which the sample is to be next transferred.

Other objects, features and advantages of the invention will become apparent from the following description of the embodiments of the invention taken in conjunction with the accompanying drawings.

### BRIEF DESCRIPTION OF THE DRAWINGS

FIG. 1 is an upper view showing an outline of an overall configuration of a vacuum processing apparatus in an embodiment of the present invention.

FIG. 2 is an upper view showing an outline of an overall configuration of a modification of the embodiment shown in FIG. 1.

### DESCRIPTION OF THE EMBODIMENTS

Referring now to the drawings, description will be given in detail of an embodiment of a vacuum processing apparatus according to the present invention.

### Embodiment

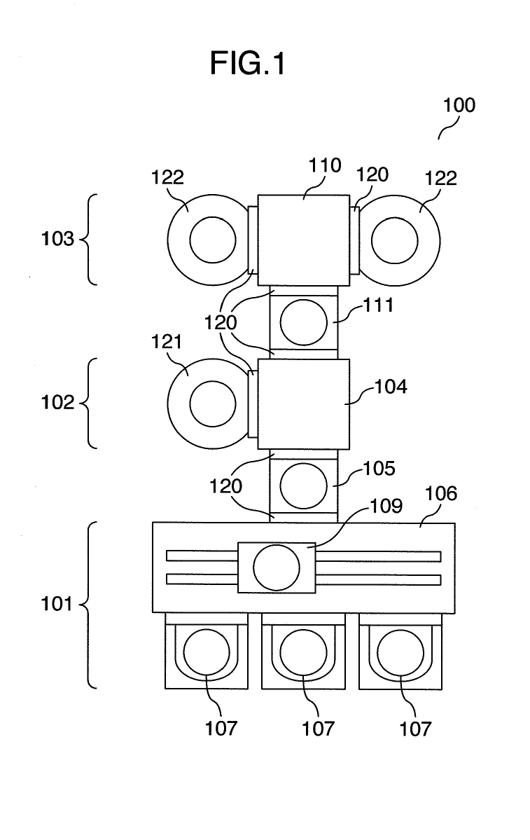

Description will now be given of an embodiment of the present invention by referring to FIG. 1. FIG. 1 shows an outline of an overall configuration of a vacuum processing apparatus in an embodiment of the present invention in an upper view. The configuration of FIG. 1 is obtained by viewing from above the vacuum processing apparatus including a plurality of processing chambers to conduct processings for samples under mutually different processing pressures.

The vacuum processing apparatus shown in FIG. 1 mainly includes an atmosphere-side block 101 and a vacuum-side block disposed on the back side thereof (the upper side on the upper view). The vacuum-side block includes a processing pressure A block 102 and a processing pressure B block 103.

In the atmosphere-side block 101, a substrate-shaped sample such as a semiconductor wafer as an object of processing is transferred, stored, or positioned under an atmospheric pressure. The vacuum-side block is a space disposed in a vacuum vessel. In the space, a sample is transferred or stored; or, plasma is generated, to conduct processing for the sample under a decompressed and predetermined pressure of vacuum.

The processing pressure A block 102 of the vacuum-side block is coupled to the atmosphere-side block 101. In this block 102, a sample is transferred through an inner space decompressed from the atmospheric pressure, and processing is conducted, by use of plasma under a condition of processing pressure A which is a predetermined value of pressure, in a processing chamber of a predetermined vacuum chamber. In the processing pressure B block 103, a sample is transferred through an inner space decompressed or compressed from processing pressure A and processing is conducted in a beforehand predetermined vacuum chamber by use of plasma under a condition of processing pressure B which is a predetermined value of pressure.

Between the processing pressure A block 102 and the atmosphere-side block 101, a lock chamber 105 is coupled to them. The lock chamber 105 is a vacuum chamber to change the pressure therein, in a state in which the sample is stored in a storing chamber, between the atmospheric pressure and processing pressure A. Further, between the processing pressure B block 103 and the processing pressure A block 102, a transfer intermediate chamber 111 is coupled thereto. The transfer intermediate chamber 111 is a storing chamber disposed in a vacuum chamber to change the pressure therein, in a state in which the sample is stored in a storing chamber, between processing pressure B and processing pressure A.

The atmosphere-side block 101 includes a housing 106 in the shape of substantially a rectangular parallelepiped. The housing 106 includes an atmosphere-side transfer robot 109 in a transfer space therein. On the front side of the housing 106, there are disposed a plurality of cassette stages 107 on which cassettes are to be installed. In each cassette, there is stored a sample to be processed or a dummy sample to be used to clean a processing chamber in a vacuum chamber.

The processing pressure A block 102 includes a vacuum transfer chamber as a vacuum chamber including a processing pressure A transfer chamber 104 in which a sample is transferred through a decompressed inside thereof. The processing pressure A transfer chamber 104 is coupled via at least one lock chamber 105 to the housing 106 of the atmosphere-side block 101.

The vacuum chamber (vacuum transfer chamber) constituting the processing pressure A transfer chamber 104 is a container. The container has, in a plan view viewed from above, the shape of a rectangle, a square, or approximately a rectangular shape which can be regarded as a rectangle or a square. In the processing pressure A transfer chamber 104 in the container, internal pressure is adjusted to processing pressure A. The vacuum transfer chamber includes sidewalls constituting a plurality of surfaces (two opposing pairs of surfaces in this example) corresponding to the sides of the rectangle. The sidewalls can be detachably coupled to a processing vessel including a processing chamber 121 in which a sample is processed under processing pressure A.

In the present embodiment, the processing vessel including the processing chamber 121 is detachably coupled to only one of the sidewalls. A vacuum chamber including a transfer intermediate chamber 111 is detachably coupled to the sidewall corresponding to one other side, and a vacuum chamber including a lock chamber 105 is detachably coupled to the sidewall corresponding to the side opposing the sidewall coupled to the transfer intermediate chamber 111

The vacuum chamber (vacuum transfer chamber) constituting the processing pressure B transfer chamber 110 is a container as in the case of the vacuum chamber (vacuum transfer chamber) constituting the processing pressure A transfer chamber 104. The container has, in a plan view viewed from above, the shape of a rectangle, a square, or approximately a rectangular shape which can be regarded as a rectangle or a square. In the processing pressure B transfer chamber 110 in the container, internal pressure is adjusted to processing pressure B. The vacuum transfer chamber also includes sidewalls constituting a plurality of surfaces (two opposing pairs of surfaces in this example) corresponding to the sides of the rectangle. The sidewalls can be detachably coupled to a processing vessel including a processing chamber 122 in which a sample is processed under processing pressure B.

In the present embodiment, the processing vessel including the processing chamber 122 is detachably coupled to only two of the sidewalls opposing each other. The transfer intermediate chamber 111 is detachably coupled to the sidewall corresponding to one other side.

Each of the processing pressure A transfer chamber 104 and the processing pressure B transfer chamber 110 includes a transfer chamber in the inside thereof as a space through which a sample is transferred. At a central position of the transfer chamber, a vacuum transfer robot 108 is disposed to transfer a sample to and from the lock chamber 105, the processing chamber 121, or the transfer intermediate chamber 111. In the processing pressure A transfer chamber 104, the vacuum transfer robot 108 including an arm places a sample on a hand in a tip end portion of the arm and holds the sample. The robot 108 then rotates and extends or contracts the arm to transfer the sample between a sample stage installed in the processing chamber 121 and a sample stage or a holding unit such as a lack to hold a sample in the storing space of the lock chamber 105 or the transfer intermediate chamber 111.

Between the processing pressure A transfer chamber 104 and each of the processing chamber 121, the lock chamber 105, and the transfer intermediate chamber 111, gates are disposed as paths to transfer a sample therebetween such that these constituent components are communicatively connected to each other by use of the gates. Between these chambers, valves 120 capable of conducting airtight closing and opening operations are disposed. The gates are opened or closed by the associated valves 120.

Description will now be given of an outline of the operation to transfer a sample when the sample is processed in the vacuum processing apparatus 100 of the present embodiment. For the samples such as semiconductor wafers stored in the cassette placed on the cassette 107, processing is started in response to an instruction signal from a controller, not shown, to regulate operation of the vacuum processing apparatus 100 or an instruction from, for example, a controller such as a host computer to control the production line in the building in which the vacuum processing apparatus 100 is installed.

When the instruction from the controller is received through wire or wirelessly via a communication unit, the atmosphere-side transfer robot 109 transfers a particular sample from a cassette. The atmosphere-side transfer robot 109 of the present embodiment is configured in multi-arm structure in which a plurality of beam-shaped members are coupled via joints to each other at both ends of the members. Through an operation to extend or to contract the multi-arm structure by rotating the arms, the robot 109 moves the hand portion which is disposed at an end portion of the multi-arm structure and which electrostatically holds the sample or which holds the sample by suction, to thereby transfer the sample from the cassette. The sample is then transferred to a positioning unit disposed at an end portion of the housing 106; or, the sample is transferred from the positioning unit to the inside of the lock chamber 105.

In the present embodiment, a controller communicatively connected via a communication unit to the vacuum processing apparatus 100 receives a signal from signal detecting units such as sensors disposed in the atmosphere-side block 101, the processing pressure A block 102, and the processing pressure B block 103 of the vacuum processing apparatus 100. Based on the signal, the vacuum processing apparatus 100 detects the associated state. According to the result of detection, a calculator disposed in the vacuum processing apparatus 100 generates an instruction signal through detection and calculation and then transmits the instruction signal to a particular constituent component of the vacuum processing apparatus 100, to thereby regulate the operation. The controller includes a communication interface to communicate signals with the communication unit, a calculator including a microprocessor such as a Central Processing Unit (CPU), a storage unit including a memory such as a Random Access Memory (RAM) and a Read Only Memory (ROM) and a hard disk unit, and a communication circuit to communicate signals between these components through wire or wirelessly.

For the lock room 105 to which the sample is transferred and is placed to be stored on a sample stage, the valve 120 disposed on the side of the housing 106 is closed and the inside thereof is sealed. The inside of the lock room 105 is then decompressed to predetermined processing pressure A. The valve 120 on the side of the processing pressure A transfer chamber 104 is then opened to communicatively connect the lock chamber 105 to the transfer chamber of the processing pressure A transfer chamber 104. The sample is transferred by the vacuum transfer robot 108 of the processing pressure A transfer chamber 104 into processing pressure A transfer chamber 104.

The vacuum transfer robot 108 of the present embodiment includes, like the atmosphere-side transfer robot 109, an arm including multi-arm structure and a hand portion. However, the hand portion does not include any unit to hold a sample by suction. The vacuum transfer robot 108 of the processing pressure A transfer chamber 104 extends, in a state in which the valve 120 is opened, the arm into the lock chamber 105 and makes the hand portion of its tip end proceed in the inside of the lock chamber 105 to receive the sample and then transfers the sample to the inside of the processing pressure A transfer chamber 104. Further, the vacuum transfer robot 108 of the processing pressure A transfer chamber 104 contracts the arm and rotates about a rotary axis disposed in the vertical direction at a center thereof, to direct the hand portion to the processing chamber 121 or the transfer intermediate chamber 111 beforehand determined when the sample is removed from the cassette. Thereafter, the vacuum transfer robot 108 of the processing pressure A extends the arm again to transfer the sample to the inside of the chamber 121 or 111.

When a sample is transferred to the transfer intermediate chamber 111, the valve 120 on the side of the processing pressure A transfer chamber 104 is closed and the inside of the transfer intermediate chamber 111 is sealed. In this situation, before the sample is transferred, the valve 120 on the side of the processing pressure B transfer chamber 110 of the transfer intermediate chamber 111 is closed. This state is retained during the transfer of the sample. After the inside of the transfer intermediate chamber 111 is sealed, the inside of the transfer intermediate chamber 111 is adjusted by decompression or compression to predetermined processing pressure B.

After the inside is adjusted to processing pressure B, the valve 120 facing the processing pressure B transfer chamber 110 of the transfer intermediate chamber 111 is opened to communicatively connect the transfer intermediate chamber 111 to the processing pressure B transfer chamber 110. The vacuum transfer robot 108 in the processing pressure B transfer chamber 110 extends its arm to the inside of the transfer intermediate chamber 111, receives the sample stored in the storing chamber of the transfer intermediate chamber 111, contracts the arm, and transfers the sample to the inside of the processing pressure B transfer chamber 110.

When the valve 120 facing the processing pressure B transfer chamber 110 of the transfer intermediate chamber 111 is closed, the vacuum transfer robot 108 of the processing pressure B transfer chamber 110 rotates about a rotary axis at the center, to direct the hand portion to the processing chamber 122 beforehand determined when the sample is remove from the cassette. After the valve 120 between the processing chamber 122 and the processing pressure B transfer chamber 110 is opened, the vacuum transfer robot 108 extends the arm again to transfer the sample held on the hand portion to the inside of the processing chamber 122. After delivering the sample to the processing chamber 122 in a space above the sample stage of the processing chamber 122, the vacuum transfer robot 108 contracts the arm and then leaves the processing chamber 122. Thereafter, the valve 120 between the processing chamber 122 and the processing pressure B transfer chamber 110 is again closed and the inside of the processing chamber 122 is sealed.

The lock chamber 105 and the transfer intermediate chamber 111 are reduced in volume to the necessary minimum value and are configured to minimize, when compressing or decompressing the pressure in the sample storing chamber therein, the period of time required to adjust the pressure. In the lock chamber 105, a sample stage or a plurality of pins on which a sample is placed to be held thereon is or are arranged. In the transfer intermediate chamber 111, a shelf structure or a lack is disposed to communicate and to deliver a sample with and to the processing pressure A transfer chamber 104 and the processing pressure B transfer chamber 110.

Although no opening is coupled to an exhaust pump to exhaust gas in the transfer intermediate chamber 111 of the present embodiment, the transfer intermediate chamber 111 may be coupled via an opening to a roughing vacuum pump such as a rotary pump to exhaust the inside of the processing pressure A transfer chamber 104 or the processing pressure B transfer chamber 110 or to decompress the chamber 104 or 110. In the present embodiment, gas having low reactivity is introduced to the insides of the lock chamber 105, the processing pressure A transfer chamber 104, and the processing pressure B transfer chamber 110. The internal pressure of each of these chambers is adjusted based on balance between exhaustion by a vacuum pump coupled to an opening to decompress the inside of the chamber and the flow rate of gas introduced to the chamber. As the gas having low reactivity, inert gases of nitrogen, argon, and the like are employed; hence, it is possible to suppress deterioration in the shape of samples after processing; for example, oxidation of surfaces of processed samples is suppressed.

In the present embodiment, the valve 120 facing the processing pressure A transfer chamber 104 or the processing pressure B transfer chamber 110 exclusively opens and closes with respect to the other valve 120 facing the processing pressure A transfer chamber 104 or the processing pressure B transfer chamber 110. That is, for the sample transferred to the transfer intermediate chamber 111, after the valve 120 to open or close the path between the transfer intermediate chamber 111 and the processing pressure A transfer chamber 104 is closed and the transfer intermediate chamber 111 is sealed and the pressure is adjusted in the inside thereof, the valve 120 to open or close the path between the transfer intermediate chamber 111 and the processing pressure B transfer chamber 110 is opened. In this situation, the other valves 120 facing the processing pressure B transfer chamber 110, i.e., two valves 120 to open or close the paths between two processing chambers 122 and the processing pressure B transfer chamber 110 are kept closed.

After the vacuum transfer robot 108 of the processing pressure B transfer chamber 110 extends, in response to an instruction from the controller, its arm to transfer the sample from the transfer intermediate chamber 111 to the inside of the processing pressure B transfer chamber 110, the valve 120 to open or to close the path between the transfer intermediate chamber 111 and the processing pressure B transfer chamber 110 is closed. Thereafter, the closed valves 120 to open or to close the paths between the processing chambers 122 and the processing pressure B transfer chamber 110 are opened. The vacuum transfer robot 108 of the processing pressure B transfer chamber 110 extends the arm and transfers the sample placed and held on the hand portion to either one processing chamber 122 predetermined when the sample is removed from the cassette and delivers the sample to the sample stage of processing chamber 122. The vacuum transfer robot 108 contracts the arm and then leaves the processing chamber 122. After the arm is stored in the processing pressure B transfer chamber 110, the valve 120 between the predetermined processing chambers 122 and the processing pressure B transfer chamber 110 is air-tightly closed and then the sample is processed under the condition of pressure B in the processing chambers 122 the inside of which is sealed.

Similarly, in a state in which the sample is transferred from the atmosphere-side block 101 to the lock chamber 105 and is stored therein and the internal pressure of the lock chamber 105 is set to a value equal to processing pressure A or to an approximate value to be regarded as a value equal to processing pressure A, the valve 120 to open or close the path between the lock chamber 105 and the processing pressure A transfer chamber 104 is opened. In this situation, the other valves 120 facing the processing pressure A transfer chamber 104, i.e., the valves 120 to open or close the paths from the processing chamber 121 and the transfer intermediate chamber 111 to the processing pressure A transfer chamber 104 and vice versa are kept closed.

After the vacuum transfer robot 108 of the processing pressure A transfer chamber 104 extends, in response to an instruction from the controller, the arm to transfer the sample from the lock chamber 105 into the processing pressure A transfer chamber 104, the valve 120 to open or close the path between the lock chamber 105 and the processing pressure A transfer chamber 104 is closed. Thereafter, the valve 120 to open or close the path between the processing chamber 121 or the transfer intermediate chamber 111 and the processing pressure A transfer chamber 104 is opened. The vacuum transfer robot 108 of the processing pressure A transfer chamber 104 extends the arm and transfers the sample placed and held on the hand portion to either one processing chamber 121 predetermined when the sample is removed from the cassette or to the transfer intermediate chamber 111 and delivers the sample to the sample stage or the shelf unit therein. The vacuum transfer robot 108 contracts the arm and then leaves the chamber 121 or 111. After the arm is stored in the processing pressure A transfer chamber 104, the valve 120 between the processing chambers 121 or the transfer intermediate chamber 111 and the processing pressure A transfer chamber 104 is air-tightly closed and the inside of the processing pressure A transfer chamber 104 is sealed.

In this state, when the sample is transferred to the processing chamber 121, process gas is introduced to the inside of the processing chamber 121. Processing is started for the sample transferred to the processing chamber 121 by using plasma under a condition of pressure A. Or, when the sample is transferred from the lock chamber 105 to the transfer intermediate chamber 111, the inside of the transfer intermediate chamber 111 is adjusted to processing pressure B.

When it is detected that the sample is completely processed in the processing chamber 121 or 122, the valve 120 to open or close the path between the pertinent processing chamber and the processing pressure A transfer chamber 104 or the processing pressure B transfer chamber 110 is exclusively opened. The vacuum transfer robot 108 transfers the processed sample to the lock chamber 105 in a reverse direction as compared with the situation in which the sample is transferred to the processing chamber. When the sample is transferred to the lock chamber 105, the valve 120 to open or close the path to communicatively connect the lock chamber 105 to the transfer chamber of the processing pressure A transfer chamber 104 is closed and the processing pressure A transfer chamber 104 is sealed, and then the pressure of the inside of the lock chamber 105 is compressed to an atmospheric pressure.

Thereafter, the valve 120 inside the housing 106 is opened to communicatively connect the inside of the lock chamber 105 to that of the housing 106, and the atmosphere-side transfer robot 109 transfers the sample from the lock chamber 105 to the original cassette to place the sample at its original position.

As above, in the present embodiment, the valve 120 facing either one transfer chamber is opened or closed in an alternative way in a state in which the other valves facing the transfer chamber are kept closed. Further, in the valves 120 respectively facing the processing pressure A transfer chamber 104 and the processing pressure B transfer chamber 110, either one valve is opened or closed in a state in which the other one valve is closed. This suppresses an event in which when the processing chambers coupled to mutually different transfer chambers are simultaneously opened, by-products and reactive gas diffuse from one of the processing chambers to the other one processing chamber to generate contaminating materials, which contaminates the processing chamber.

In the present embodiment, the vacuum transfer robot 108 includes a plurality of arms (two in this example) and is capable of holding a plurality of samples on the respective hand portions. In operation of the vacuum transfer robot 108, in a state in which a sample to be processed or a processed sample is held on a first arm contracted, the vacuum transfer robot 108 extends a second arm to a target processing chamber to receive a processed sample or a sample to be processed and then contracts the arm. Further, the vacuum transfer robot 108 extends the first arm to the target processing chamber and transfers the processed sample or the to-be-processed sample held by the hand portion to deliver the sample to the target processing chamber, to thereby conduct a so-called replacing operation.

That is, in operation of each of the vacuum transfer robots 108, the valve 120 is opened or closed in a state in which a first vacuum transfer robot 108 assigned to the processing pressure A transfer chamber 104 holds a sample on its first arm in the processing pressure A transfer chamber 104 and a second vacuum transfer robot 108 assigned to the processing pressure B transfer chamber 110 holds a sample on its first arm in the processing pressure B transfer chamber 110. Or, each of the vacuum transfer robots 108 holds the sample on its first arm until the valve 120 is opened.

The vacuum transfer robots 108 of the present embodiment can concurrently transfer samples in the processing pressure A block 102 and the processing pressure B block 103 which are respectively sectioned as airtight blocks. Hence, the sample processing efficiency is improved and the throughput, i.e., the number of wafers processed per unitary time by the vacuum processing apparatus is increased.

### [Modification]

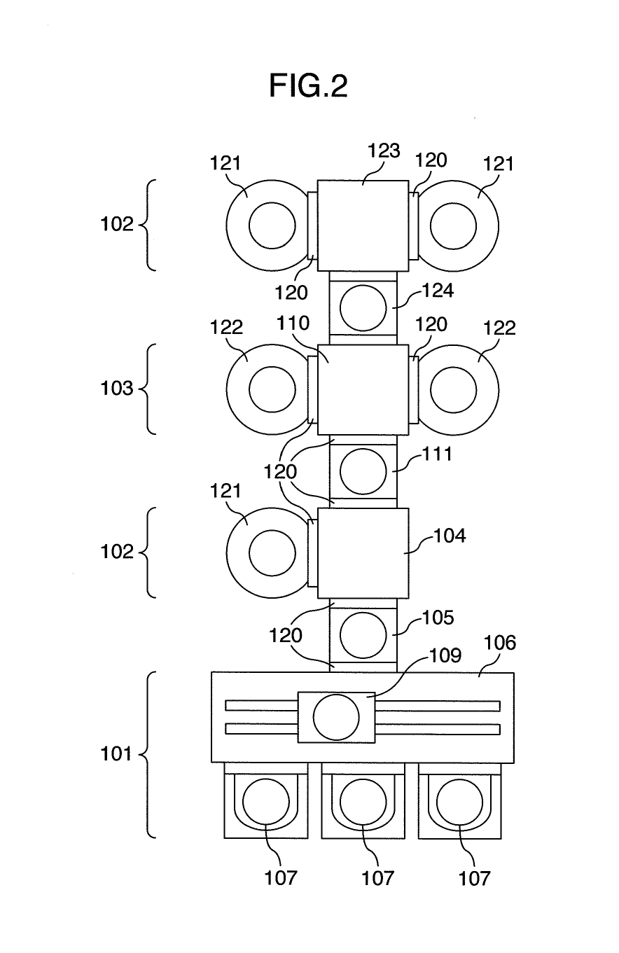

FIG. 2 shows a modification of the embodiment of FIG. 1 and is implemented by additionally including a third processing pressure A transfer chamber 123, a transfer intermediate chamber 124, and two processing chambers 121 in the third processing pressure A transfer chamber 123. In this configuration of the vacuum processing apparatus, a sample to be transferred from the transfer intermediate chamber 124 to the third processing pressure A transfer chamber 123 is compressed or decompressed to predetermined pressure in the transfer intermediate chamber 124. Thereafter, the valve 120 facing the third processing pressure A transfer chamber 123 is opened to communicatively connect the transfer intermediate chamber 124 to the third processing pressure A transfer chamber 123. The vacuum transfer robot 108 of the third processing pressure A transfer chamber 123 extends its arm to the inside of the transfer intermediate chamber 124 to transfer the sample from the transfer intermediate chamber 124 to the third processing pressure A transfer chamber 123. The vacuum transfer robot 108 then transfers the sample on the arm to either one processing chamber 121 predetermined when the sample is removed from the cassette.

Also in this configuration, the pressure is changed in the transfer intermediate chamber 124 the processing chamber of which has a small volume. Hence, it is possible to minimize the period of time required to change the pressure, to thereby conduct operation with optimal production efficiency.

According to the embodiment, it is possible to provide a highly-productive semiconductor manufacturing apparatus to which a plurality of processing chambers to be used under mutually different processing pressure conditions are connected.

Further, it is possible to provide a semiconductor manufacturing apparatus in which even when different processings are conducted in vacuum and under an atmospheric pressure, the wafers are not exposed to the atmospheric environment and are not deteriorated, for example, are not oxidized.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus, comprising:
an atmospheric transfer chamber including on a front side thereof a plurality of cassette stages on which cassettes having stored therein samples as processing objects are to be mounted;
a first transfer chamber disposed on a back side of the atmospheric transfer chamber, the first transfer chamber comprising an inside, any one of the samples transferred through a lock chamber being transferred through the inside decompressed to first pressure;
a second transfer chamber disposed on a back side of the first transfer chamber and coupled to the first transfer chamber via a relay chamber capable of adjusting pressure thereof, the second transfer chamber comprising an inside, the sample transferred from the first transfer chamber being transferred through the inside decompressed to second pressure;
a first processing vessel coupled to the first transfer chamber, the first processing vessel comprising an inside and a processing chamber therein, the sample being transferred to the processing chamber in the inside set to the first pressure and being processed therein; and
a second processing vessel coupled to the second transfer chamber, the second processing vessel comprising an inside and a processing chamber therein, the sample being transferred to the processing chamber in the inside set to the second pressure and being processed therein.

2. A vacuum processing apparatus according to claim 1, wherein:
the relay chamber in which the sample is stored and which is sealed adjusts inner pressure thereof to the first or second pressure of the first or second transfer chamber to which the sample is to be next transferred.

3. A vacuum processing apparatus according to claim 2, comprising:
a plurality of valves for the first transfer chamber, the valves being disposed between the first transfer chamber and each of the lock chamber, the relay chamber, and the first processing chamber, to air-tightly open or close paths therebetween;
a plurality of valves for the second transfer chamber, the valves being disposed between the second transfer chamber and each of the relay chamber and the second processing chamber, to air-tightly open or close paths therebetween, wherein
in a state in which the first transfer chamber and the second transfer chamber are air-tightly separated from each other, after the valves for the first transfer chamber and the valves for the second transfer chamber are respectively opened in an exclusive fashion and the sample is transferred, the valves are closed.

4. An operation method of a vacuum processing apparatus, the apparatus comprising:
an atmospheric transfer chamber including on a front side thereof a plurality of cassette stages on which cassettes having stored therein samples as processing objects are to be mounted;
a first transfer chamber disposed on a back side of the atmospheric transfer chamber, the first transfer chamber comprising an inside, any one of the samples transferred through a lock chamber being transferred through the inside decompressed to first pressure;
a second transfer chamber disposed on a back side of the first transfer chamber and coupled to the first transfer chamber via a relay chamber capable of adjusting pressure thereof, the second transfer chamber comprising an inside, the sample transferred from the first transfer chamber being transferred through the inside decompressed to second pressure;
a first processing vessel coupled to the first transfer chamber, the first processing vessel comprising an inside and a processing chamber therein, the sample being transferred to the processing chamber in the inside set to the first pressure and being processed therein; and
a second processing vessel coupled to the second transfer chamber, the second processing vessel comprising an inside and a processing chamber therein, the sample being transferred to the processing chamber in the inside set to the second pressure and being processed therein, wherein
the relay chamber in which the sample is stored and which is sealed adjusts inner pressure thereof to the first or second pressure of the first or second transfer chamber to which the sample is to be next transferred.

5. An operation method of a vacuum processing apparatus according to claim 4, the apparatus comprising:
a plurality of valves for the first transfer chamber, the valves being disposed between the first transfer chamber and each of the lock chamber, the relay chamber, and the first processing chamber, to air-tightly open or close paths therebetween;
a plurality of valves for the second transfer chamber, the valves being disposed between the second transfer chamber and each of the relay chamber and the second processing chamber, to air-tightly open or close paths therebetween, wherein
in a state in which the first transfer chamber and the second transfer chamber are air-tightly separated from each other, after the valves for the first transfer chamber and the valves for the second transfer chamber are respectively opened in an exclusive fashion and the sample is transferred, the valves are closed.
